(19) United States
(12) Patent Application Publication
(10) Pub. No.: US 2024/0186409 A1
(43) Pub. Date: Jun. 6, 2024

(54) INTEGRATED CIRCUIT DEVICE INCLUDING A LATERAL DIFFUSED METAL OXIDE SEMICONDUCTOR

(71) Applicant: SAMSUNG ELECTRONICS CO., LTD., Suwon-Si (KR)

(72) Inventors: Wooyeol MAENG, Suwon-si (KR); Hyungjin Lee, Suwon-si (KR); Huichul Shin, Suwon-si (KR)

(21) Appl. No.: 18/372,325

(22) Filed: Sep. 25, 2023

(30) Foreign Application Priority Data
Dec. 5, 2022 (KR) 10-2022-0168131

(51) Int. Cl. H01L 29/78; H01L 29/06

(52) U.S. Cl. CPC H01L 29/7816; H01L 29/0649; H01L 29/7851

(57) ABSTRACT

An integrated circuit device includes: a semiconductor substrate; first and second conductivity type wells formed in the semiconductor substrate; a source region formed in the second conductivity type well; a drain region formed in the first conductivity type well; a recess insulating layer disposed between the source region and the drain region, and including an upper insulating unit and a lower insulating unit, wherein the upper insulating unit fills an upper substrate recess that extends from an upper surface of the first conductivity type well, and wherein the lower insulating unit fills a lower substrate recess that extends from the upper substrate recess; and a gate electrode layer arranged on the first and second conductivity type wells, and wherein the recess insulating layer has a shape in which both sides thereof are asymmetric with respect to a center of the upper insulating unit.

### CROSS-REFERENCE TO RELATED APPLICATION

This application claims priority under 35 U.S.C. § 119 to Korean Patent Application No. 10-2022-0168131, filed on Dec. 5, 2022 in the Korean Intellectual Property Office, the disclosure of which is incorporated by reference herein in its entirety.

### TECHNICAL FIELD

The present inventive concept relates to an integrated circuit device, and more particularly, to an integrated circuit device including a lateral diffused metal oxide semiconductor (LDMOS).

### DISCUSSION OF THE RELATED ART

Demand for power semiconductor devices is rapidly increasing due to the recent increase in the improvements of mobile devices, such as mobile phones, laptops, and personal computers (PCs). To improve high voltage characteristics in the power semiconductor devices, integrated circuit devices including LDMOS transistors have been under development.

### SUMMARY

According to an embodiment of the present inventive concept, an integrated circuit device includes: a semiconductor substrate; a first conductivity type well and a second conductivity type well formed in the semiconductor substrate; a source region formed in the second conductivity type well; a drain region formed in the first conductivity type well; a recess insulating layer disposed between the source region and the drain region, and including an upper insulating unit and a lower insulating unit, wherein the upper insulating unit fills an upper substrate recess that extends from an upper surface of the first conductivity type well and into the first conductivity type well, and wherein the lower insulating unit fills a lower substrate recess that extends from a bottom surface of the upper substrate recess and into the first conductivity type well; and a gate electrode layer disposed between the source region and the recess insulating layer, and arranged on the first conductivity type well and the second conductivity type well, and wherein the recess insulating layer has a shape in which both sides thereof are asymmetric with respect to a center of the upper insulating unit.

According to an embodiment of the present inventive concept, an integrated circuit device includes: a semiconductor substrate including a fin-type active region protruding in a vertical direction; a first conductivity type well and a second conductivity type well arranged in a first horizontal direction and in a portion of the semiconductor substrate that includes the fin-type active region; a source region formed in the second conductivity type well; a drain region formed in the first conductivity type well; a recess insulating layer disposed between the source region and the drain region, and including an upper insulating unit and a lower insulating unit, wherein the upper insulating unit extends from an upper surface of the first conductivity type well and into the first conductivity type well, and fills an upper substrate recess having a first length in the first horizontal direction, and wherein the lower insulating unit extends from a bottom surface of the upper substrate recess and into the first conductivity type well, and fills a lower substrate recess having a second length that is less than the first length in the first horizontal direction; and a gate electrode layer disposed between the source region and the recess insulating layer, and arranged on the first conductivity type well and the second conductivity type well, wherein the gate electrode layer covers an upper surface and side surfaces of the fin-type active region, wherein the recess insulating layer has a shape in which both sides thereof are asymmetric with respect to a center of the upper insulating unit.

According to an embodiment of the present inventive concept, an integrated circuit device includes: a semiconductor substrate including a fin-type active region protruding in a first direction; a first conductivity type well and a second conductivity type well arranged in a second direction and in a portion of the semiconductor substrate that includes the fin-type active region; a source region formed in the second conductivity type well; a drain region formed in the first conductivity type well; a recess insulating layer disposed between the source region and the drain region, and including an upper insulating unit and a lower insulating unit, wherein the upper insulating unit extends from an upper surface of the first conductivity type well and into the first conductivity type well, and fills an upper substrate recess having a first length in the second direction, and wherein the lower insulating unit extends from a bottom surface of the upper substrate recess and into the first conductivity type well, and fills a lower substrate recess having a second length that is less than the first length in the second direction; a gate electrode layer disposed between the source region and the recess insulating layer, and arranged on the first conductivity type well and the second conductivity type well, wherein the gate electrode layer covers an upper surface and side surfaces of the fin-type active region; and a gate insulating layer arranged between the gate electrode layer and the first conductivity type well, and between the gate electrode layer and the second conductivity type well, wherein the lower insulating unit is more shifted toward the source region with respect to a center of the upper insulating unit in the second direction than to the drain region, and one side of the upper insulating unit, which faces the source region, and one side of the lower insulating unit are spaced apart from each other, and wherein the recess insulating layer has a shape in which both sides thereof are asymmetric with respect to the center of the upper insulating unit.

### BRIEF DESCRIPTION OF THE DRAWINGS

The above and other aspects of the present inventive concept will become more apparent by describing in detail embodiments thereof, with reference to the accompanying drawings, in which:

FIGS. 1, 2A, 2B, 2C, 3, 4, 5, 6, 7, 8, 9, 10 and 11 are cross-sectional views and plan views describing a method of manufacturing an integrated circuit device, according to an embodiment of the present inventive concept;

FIGS. 12A and 12B are cross-sectional views of an integrated circuit device according to some embodiments of the present inventive concept;

FIGS. 13 and 14 are cross-sectional views describing a method of manufacturing a semiconductor device, according to an embodiment of the present inventive concept;

FIG. 15 is a cross-sectional view of an integrated circuit device according to an embodiment of the present inventive concept:

FIGS. 16 and 17 are cross-sectional views describing a method of manufacturing a semiconductor device, according to an embodiment of the present inventive concept; and

FIG. 18 is a cross-sectional view of an integrated circuit device according to an embodiment of the present inventive concept.

### DETAILED DESCRIPTION OF THE EMBODIMENTS

In the present inventive concept, the term “metal-oxide-semiconductor (MOS)” is a term widely used in the art, “M” is not limited to metal but may include various kinds of conductors, and “S” may include a substrate or a semiconductor structure. In addition, “O” is not limited to oxides, but may include various types of inorganic or organic substances. The term “semiconductor” may include single crystal, polycrystalline, amorphous, Group 4, or compound semiconductors. Furthermore, the conductive or doping regions of the components may be “P-type” or “N-type” depending on the characteristics of the main carrier, but this is only for convenience of explanation, and the present inventive concept is not limited to thereto. For example, the “P-type” or “N-type” may be used as a more general term, the “first conductivity type” or “second conductivity type”, where the first conductivity type may be P-type or N-type, and the second conductivity type may be N-type or P-type.

In the descriptions below, N-channel lateral diffused metal oxide semiconductor (LDMOS) transistors are used as examples to describe integrated circuit devices according to some embodiment of the present inventive concept. However, this is for convenience of explanation, and the present inventive concept is not limited thereto. Various modifications and changes may be made within the scope of the present inventive concept to provide various integrated circuit devices and circuits including at least one of a P-channel LDMOS transistor, a combination of a P-channel LDMOS transistor and an N-channel LDMOS transistor, an N-channel extended-drain MOS (EDMOS) transistor, a P-channel EDMOS transistor, and/or a combination of a P-channel EDMOS transistor and an N-channel EDMOS transistor.

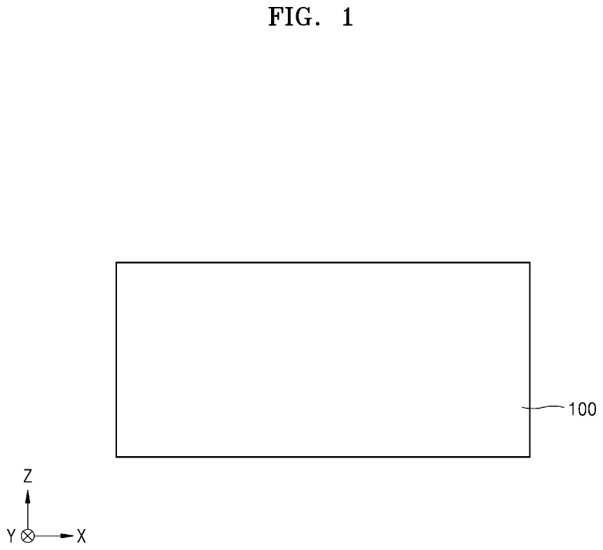

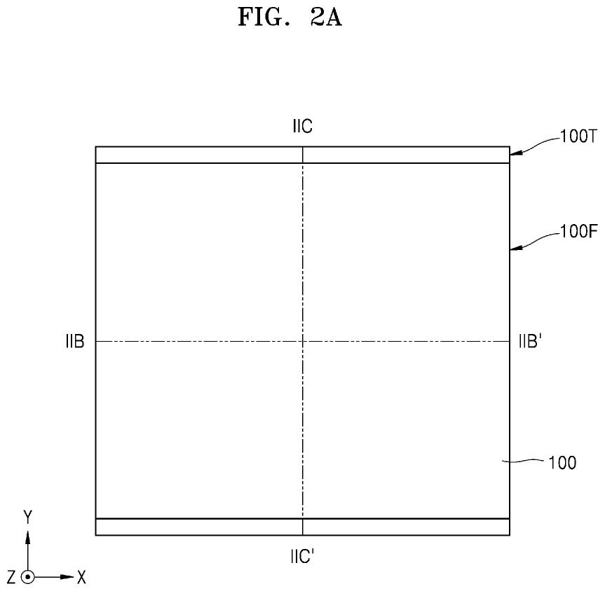

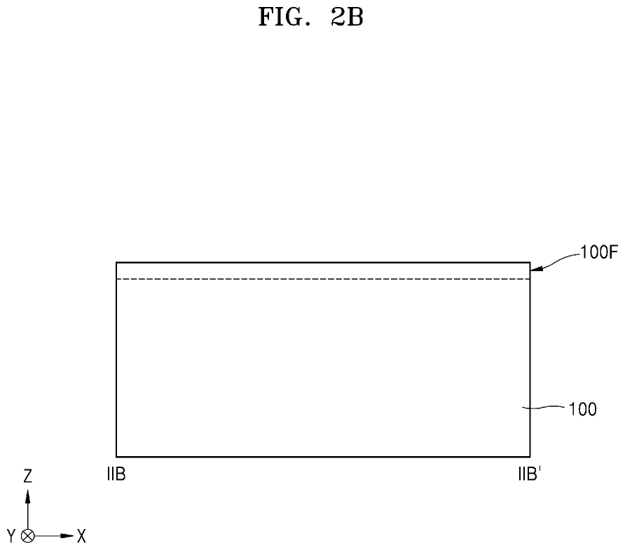

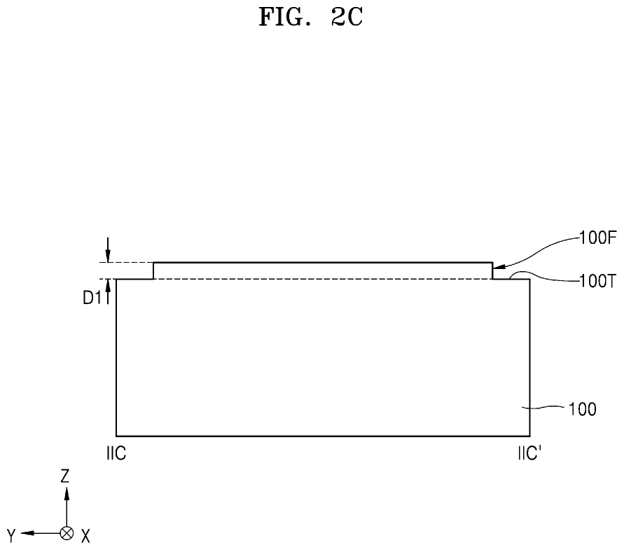

FIGS. 1 through 11 are cross-sectional views and plan views describing a method of manufacturing an integrated circuit device, according to an embodiment of the present inventive concept. FIG. 2B is a cross-sectional view taken along line IIB-IIIB′ in FIG. 2A, FIG. 2C is a cross-sectional view taken along line IIC-IIC′ in FIG. 2A, and FIGS. 1, 3, 4, 5, 6, 7, 8, 9, 10, and 11 are cross-sectional views taken along line IIB-IIB′ in FIG. 2A.

Referring to FIG. 1, a semiconductor substrate 100 may be prepared. In some embodiments of the present inventive concept, the semiconductor substrate 100 may include a bulk substrate. For example, the “bulk substrate” may be a substrate including semiconductors only. In some embodiments of the present inventive concept, the semiconductor substrate 100 may include, for example, silicon (Si), crystalline Si, polycrystalline Si, or amorphous Si. In some embodiments of the present inventive concept, the semiconductor substrate 100 may include a semiconductor element such as germanium (Ge), or at least one of silicon germanium (SiGe), silicon carbide (SiC), silicon tin (SiSn), gallium arsenide (GaAs), gallium phosphide (GaP), gallium nitride (GaN), indium arsenide (InAs), indium phosphide (InP), lead sulfide (PbS), and/or zinc selenide (ZnSe), but the present inventive concept is not necessarily limited thereto. In some embodiments of the present inventive concept, the semiconductor substrate 100 may have a silicon on insulator (SOI) structure. For example, the semiconductor substrate 100 may include a buried oxide (BOX) layer.

Referring to FIGS. 2A through 2C together, by etching a portion of the semiconductor substrate 100, a substrate trench 100T and a fin-type active region 100F which is defined by the substrate trench 100T and protrudes in a vertical direction (e.g., a Z direction) from a bottom surface of the substrate trench 100T. The fin-type active region 100F may extend in a first horizontal direction (e.g., a X direction), and may have a horizontal width of about 1 μm to about 5 μm in a second horizontal direction (e.g., a Y direction) substantially perpendicular to the first horizontal direction (e.g., the X direction). The substrate trench 100T may have a first depth D1 from a top surface of the fin-type active region 100F, and the fin-type active region 100F may protrude with a height equal to the first depth D1 from a bottom surface of the substrate trench 100T in the vertical direction (e.g., the Z direction). The first depth D1 may be several tens of A. For example, the first depth D1 may be about 30 Å to about 50 Å.

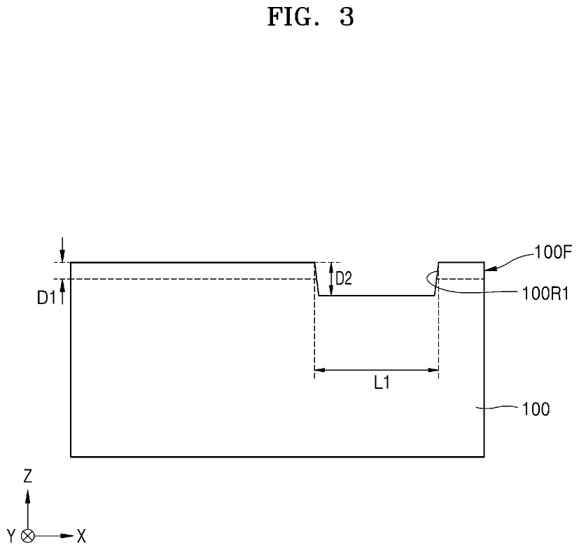

Referring to FIG. 3, by etching a portion of the semiconductor substrate 100, an upper substrate recess 100R1 may be formed. The upper substrate recess 100R1 may be formed by removing a portion of the semiconductor substrate 100 from the upper surface of the fin-type active region 100F. The upper substrate recess 100R1 may have a second depth D2, which is greater than the first depth D1, from the upper surface of the fin-type active region 100F. The second depth D2 may be several tens of nm. For example, the second depth D2 may be about 60 nm to about 90 nm.

The upper substrate recess 100R1 may have a first length L1 in the first horizontal direction (e.g., the X direction). In some embodiments of the present inventive concept, the upper substrate recess 100R1 may have a tapered shape which extends into the semiconductor substrate 100 with a decreasing length as the upper substrate recess 100R1 extends toward a lower surface of the semiconductor substrate 100. For example, the upper substrate recess 100R1 may have an equilateral trapezoidal cross-section having a bottom surface shorter than a top side thereof on an X-Z plane (e.g., a plane extending in the first horizontal direction (X direction) and the vertical direction (Z direction)), and the first length L1 of the upper substrate recess 100R1 may be the length of the top side thereof. The first length L1 may be several hundreds of nm. For example, the first length L1 may be about 400 nm to about 800 nm.

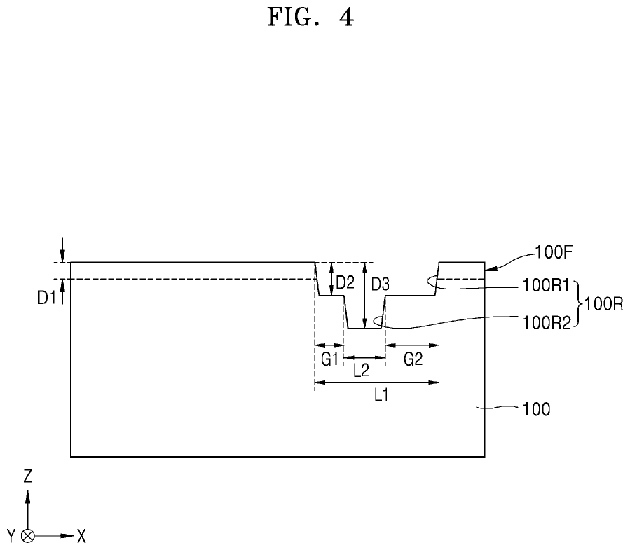

Referring to FIG. 4, by etching a portion of the semiconductor substrate 100, a lower substrate recess 100R2 may be formed. The lower substrate recess 100R2 may be interconnected to the upper substrate recess 100R1. For example, the lower substrate recess 100R2 may be formed by removing a portion of the semiconductor substrate 100 from the bottom surface of the upper substrate recess 100R1. The lower substrate recess 100R2 may have a third depth D3, which is greater than the second depth D2, from the upper surface of the fin-type active region 100F. The third depth D3 may be several hundreds of nm. For example, the third depth D3 may be about 150 nm to about 300 nm. The depth of the lower substrate recess 100R2 from the bottom of the upper substrate recess 100R1 may be a difference between the third depth D3 and the second depth D2. For example, the depth of the lower substrate recess 100R2 from the bottom of the upper substrate recess 100R1 may be about 90 nm to about 240 nm. The depth of the lower substrate recess 100R2 from the bottom of the upper substrate recess 100R1 may be greater than the second depth D2.

The upper substrate recess 100R1 and the lower substrate recess 100R2, which are interconnected to each other, may be referred to as the substrate recess 100R. In some embodiments of the present inventive concept, the substrate recess 100R may have a T-shape on the X-Z plane.

The lower substrate recess 100R2 may have a second length L2 shorter than the first length L1 in the first horizontal direction (e.g., the X direction). In some embodiments of the present inventive concept, the lower substrate recess 100R2 may have a tapered shape which extends into the semiconductor substrate 100 with a decreasing length as the lower substrate recess 100R2 approaches a lower surface of the semiconductor substrate 100. For example, the lower substrate recess 100R2 may have an equilateral trapezoidal cross-section with a bottom side less than a top side in the X-Z plane, and the second length L2 of the lower substrate recess 100R2 may be the length of the top side having the largest length for the lower substrate recess 100R2. For example, the second length L2 may be about 100 nm to about 300 nm.

The center of the lower substrate recess 100R2 may be shifted to one side in the first horizontal direction (e.g., the X direction) with respect to the center of the upper substrate recess 100R1. For example, the substrate recess 100R may have a shape in which both sides thereof are asymmetric with respect to the center of the upper substrate recess 100R1 in the first horizontal direction (e.g., the X direction).

One side of the upper substrate recess 100R1 and one side of the lower substrate recess 100R2 may be spaced apart from each other by a first gap G1 in the first horizontal direction (e.g., the X direction), and the other side of the upper substrate recess 100R1 and the other side of the lower substrate recess 100R2 may be spaced apart from each other by a second gap G2 that is different from the first gap G1. In some embodiments of the present inventive concept, the first gap G1 may be less than the second gap G2. For example, the first gap G1 may be about 100 nm to about 200 nm, and the second gap G2 may be about 200 nm to about 300 nm. In some embodiments of the present inventive concept, the first gap G1 may be less than the second length L2.

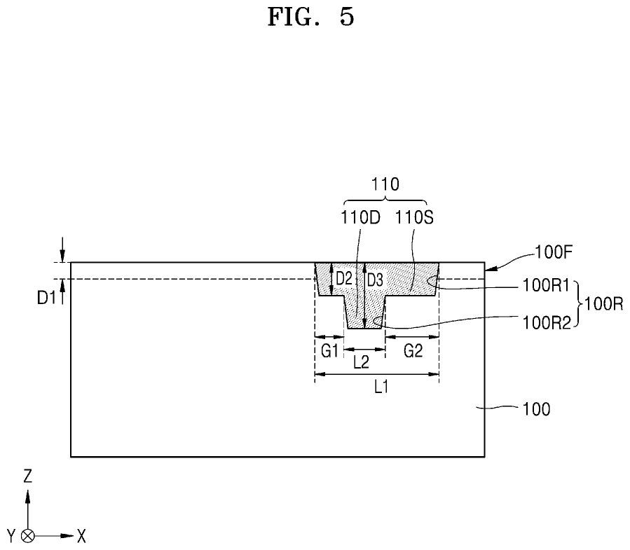

Referring to FIG. 5, a recess insulating layer 110 filling the substrate recess 100R may be formed. The recess insulating layer 110 may include, for example, oxide. The recess insulating layer 110 may include an upper insulating unit 110S, which fills the upper substrate recess 100R1, and a lower insulating unit 110D, which fills the lower substrate recess 100R2. Because the lower insulating unit 110D, which is a portion of the recess insulating layer 110, fills the lower substrate recess 100R2 that is interconnected to the upper substrate recess 100R1, the lower insulating unit 110D may be arranged below the upper insulating unit 110S. In addition, the lower insulating unit 110D may overlap the upper insulating unit 110S in the vertical direction (e.g., the Z direction). The upper insulating unit 110S and the lower insulating unit 110D may be formed together, and may include the same material. For example, the upper insulating unit 110S and the lower insulating unit 110D may be a single body. The upper insulating unit 110S and the lower insulating unit 110D may be referred to as a shallow insulating unit and a deep insulating unit.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length as the upper insulating unit 110S approaches a lower surface of the semiconductor substrate 100. For example, the upper insulating unit 110S may have an equilateral trapezoidal cross-section with a bottom side less than a top side in the X-Z plane, and the first length L1 of the upper insulating unit 110S may be the length of the top side having the largest length for the upper insulating unit 110S. The first length L1 may be several hundreds of nm. For example, the first length L1 may be about 400 nm to about 800 nm.

An upper surface of the recess insulating layer 110 (i.e., an upper surface of the upper insulating unit 110S) and an upper surface of the fin-type active region 100F may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F. The thickness of the upper insulating unit 110S may be several tens of nm. For example, the thickness of the upper insulating unit 110S may be about 60 nm to about 80 nm.

The lower insulating unit 110D may have the second length L2 less than the first length L1 in the first horizontal direction (e.g., the X direction). The lower insulating unit 110D may have a tapered shape extending from a lower surface of the upper insulating unit 110S into the semiconductor substrate 100 with a decreasing length as the lower insulating unit 110D approaches a lower surface of the semiconductor substrate 100. For example, the lower insulating unit 110D may have an equilateral trapezoidal cross-section with a bottom side less than a top side in the X-Z plane, and the second length L2 of the lower insulating unit 110D may be the length of the top side having the largest length of the lower insulating unit 110D. For example, the second length L2 may be about 100 nm to about 300 nm.

The thickness of the lower insulating unit 110D may be a difference between the third depth D3 and the second depth D2. For example, the thickness of the lower insulating unit 110D may be about 90 nm to about 240 nm.

The center of the lower insulating unit 110D may be shifted to one side of the upper insulating unit 110S in the first horizontal direction (e.g., the X direction) with respect to the center of the upper insulating unit 110S. For example, the recess insulating layer 110 may have a shape in which both sides thereof are asymmetric with respect to the center of the upper insulating unit 110S in the first horizontal direction (e.g., the X direction).

One side of the upper insulating unit 110S and one side of the lower insulating unit 110D may be spaced apart from each other by the first gap G1 in the first horizontal direction (e.g., the X direction), and the other side of the upper insulating unit 110S and the other side of the lower insulating unit 110D may be spaced apart from each other by the second gap G2 that is different from the first gap G1. In some embodiments of the present inventive concept, the first gap G1 may be less than the second gap G2. For example, the first gap G1 may be about 100 nm to about 200 nm, and the second gap G2 may be about 200 nm to about 300 nm. In some embodiments of the present inventive concept, the first gap G1 may be less than the second length L2.

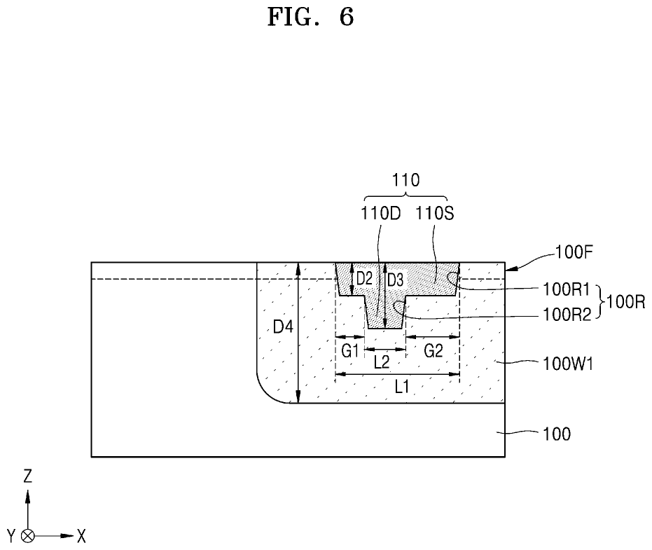

Referring to FIG. 6, a first conductivity type well 100W1 may be formed in the semiconductor substrate 100. The first conductivity type well 100W1 may be formed to at least partially surround the recess insulating layer 110. For example, the first conductivity type well 100W1 may be formed by injecting impurities of the first conductivity type into a portion of the semiconductor substrate 100 that is adjacent to the recess insulating layer 110. The first conductivity type may include the N-type, and the first conductivity type well 100W1 may include the N-type well. The first conductivity type well 100W1 may be referred to as a first conductivity type drift region.

The first conductivity type well 100W1 may be formed to have a fourth depth D4, which is greater than the third depth D3, from the upper surface of the fin-type active region 100F or the upper surface of the recess insulating layer 110. The first conductivity type well 100W1 may be formed to have a lower surface lower than a lower surface of the recess insulating layer 110, and to at least partially surround side surfaces and the lower surface of the recess insulating layer 110.

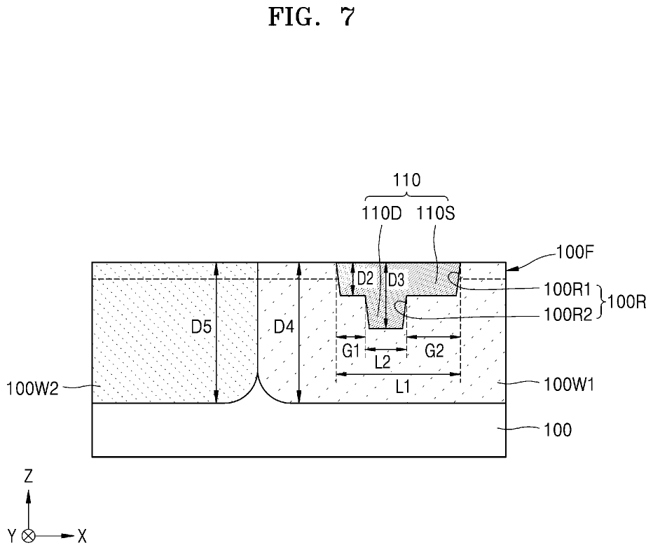

Referring to FIG. 7, a second conductivity type well 100W2 may be formed in the semiconductor substrate 100. The second conductivity type well 100W2 may be formed to be spaced apart from the recess insulating layer 110. For example, the first conductivity type well 100W1 may be disposed between the second conductivity type well 100W2 and the recess insulating layer 110. The second conductivity type well 100W2 may be formed to be adjacent to the first conductivity type well 100W1. For example, the second conductivity type well 100W2 may be formed to be in contact with the first conductivity type well 100W1. An upper surface of the first conductivity type well 100W1, an upper surface of the second conductivity type well 100W2, and the upper surface of the recess insulating layer 110 may be at substantially the same vertical level as each other to be substantially coplanar with each other. The second conductivity type well 100W2 may be formed by injecting impurities of a second conductivity type into a portion of the semiconductor substrate 100 where the first conductivity type well 100W1 and the recess insulating layer 110 are not arranged. The second conductivity type may include the P-type, and the second conductivity type well 100W2 may include the P-type well. For example, the first conductivity type well 100W1 may be formed in a portion of the fin-type active region 100F, and the second conductivity type well 100W2 may be formed in another portion of the fin-type active region 100F.

The second conductivity type well 100W2 may be formed to have a fifth depth D5, which is greater than the third depth D3, from the upper surface of the fin-type active region 100F or the upper surface of the recess insulating layer 110. In some embodiments of the present inventive concept, the fifth depth D5 may be substantially the same as the fourth depth D4, but the present inventive concept is not necessarily limited thereto.

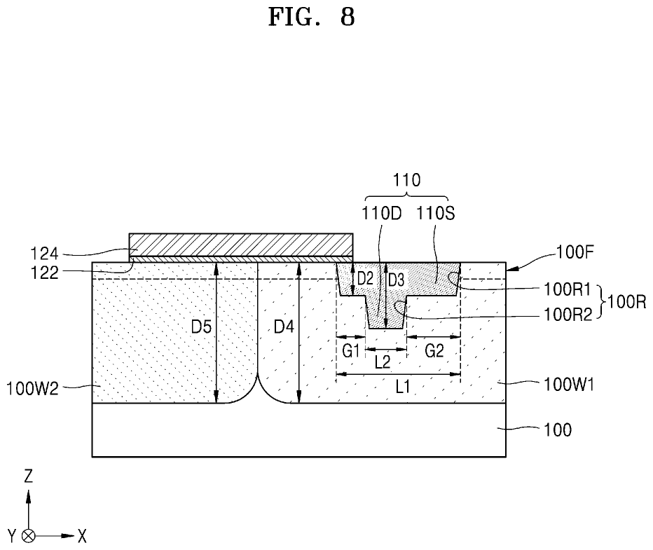

Referring to FIG. 8, a dummy gate insulating layer 122 and a dummy gate electrode layer 124 may be sequentially formed on the fin-type active region 100F. For example, the dummy gate insulating layer 122 may be formed to include silicon oxide, and the dummy gate electrode layer 124 may be formed to include polysilicon. The dummy gate insulating layer 122 and the dummy gate electrode layer 124 may be formed to overlap a portion of the first conductivity type well 100W1 and a portion of the second conductivity type well 100W2 in the vertical direction (e.g., the Z direction). The dummy gate insulating layer 122 and the dummy gate electrode layer 124 may be formed by forming a dummy insulating material layer and a dummy electrode material layer covering the semiconductor substrate 100, and then patterning the dummy insulating material layer and the dummy electrode material layer.

The dummy gate insulating layer 122 and the dummy gate electrode layer 124 may be formed to cover a portion of the recess insulating layer 110. For example, the dummy gate insulating layer 122 and the dummy gate electrode layer 124 may be formed to overlap a portion of the upper insulating unit 110S in the vertical direction (e.g., the Z direction). The dummy gate insulating layer 122 and the dummy gate electrode layer 124 may be formed not to overlap the lower insulating unit 110D in the vertical direction (e.g., the Z direction).

In some embodiments of the present inventive concept, the dummy gate insulating layer 122 and the dummy gate electrode layer 124 may be formed to cover the top and side surfaces of the fin-type active region 100F. For example, the dummy gate insulating layer 122 may extend from the top surface of the fin-type active region 100F and along the side surface of the fin-type active region 100F to contact the bottom surface of the substrate trench 100T, and the dummy gate electrode layer 124 may cover the top surface of the dummy gate insulating layer 122.

The length of the dummy gate insulating layer 122 and the dummy gate electrode layer 124 may be about 1 μm to about 2 μm in the first horizontal direction (e.g., the X direction), and the width thereof may be about 1 μm to about 5 μm in the second horizontal direction (e.g., the Y direction).

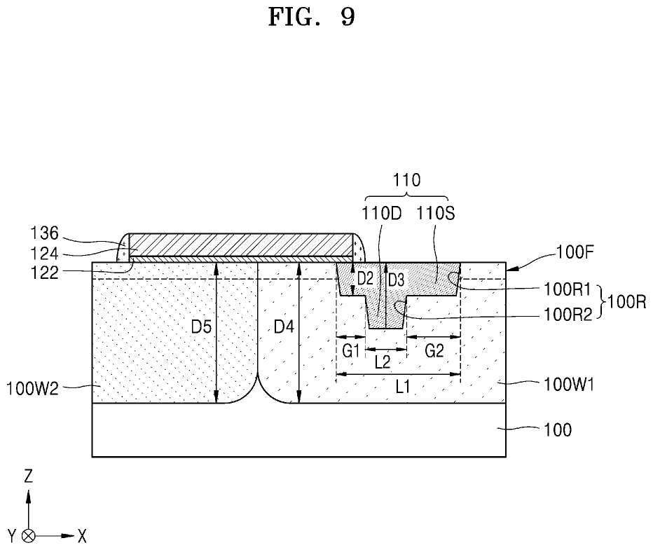

Referring to FIG. 9, a gate spacer 136 covering the side surfaces of the dummy gate insulating layer 122 and the dummy gate electrode layer 124 may be formed. The gate spacer 136 may be formed by forming a spacer insulating material layer covering the semiconductor substrate 100, on which the dummy gate insulating layer 122 and the dummy gate electrode layer 124 are formed, and then, performing an anisotropic etching process. In addition, the method for forming the gate spacer 136 may include maintaining only a portion of the spacer insulating material layer that is covering the dummy gate insulating layer 122 and side surfaces of the dummy gate electrode layer 124. The gate spacer 136 may be formed to include nitride. For example, the gate spacer 136 may include silicon nitride.

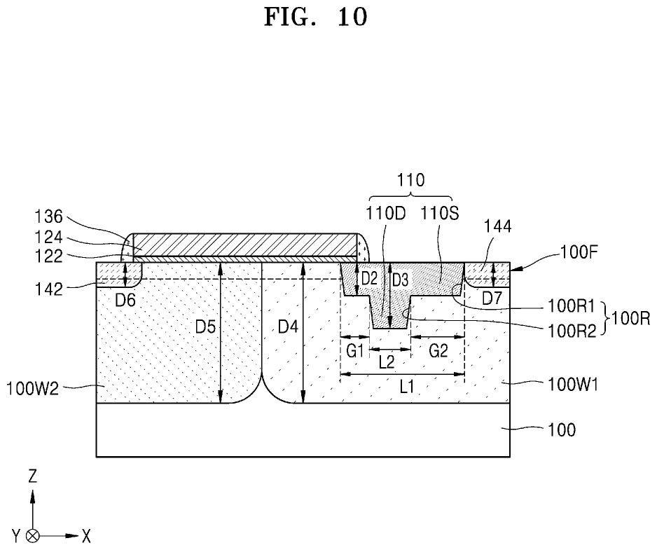

Referring to FIG. 10, a source region 142 may be formed in a portion of the second conductivity type well 100W2, and a drain region 144 may be formed in a portion of the first conductivity type well 100W1. The source region 142 may be formed by injecting impurities having the first conductivity type via a portion of the upper surface of the second conductivity type well 100W2, which is exposed by the dummy gate insulating layer 122, the dummy gate electrode layer 124, and the gate spacer 136, and the drain region 144 may be formed by injecting impurities having the first conductivity type via a portion of the upper surface of the first conductivity type well 100W1, which is exposed by the dummy gate insulating layer 122, the dummy gate electrode layer 124, and the gate spacer 136. For example, the source region 142 and the drain region 144 may include an N+ type doping region having a doping concentration higher than that of the first conductivity type well 100W1. The source region 142 may be surrounded by the second conductivity type well 100W2, and the drain region 144 may be surrounded by the first conductivity type well 100W1 and the recess insulating layer 110.

The source region 142 may have a lower surface at a sixth depth D6, which is greater than the first depth D1, from the upper surface of the fin-type active region 100F, and the drain region 144 may have a lower surface at a seventh depth D7, which is greater than the first depth D1, from the upper surface of the fin-type active region 100F. In some embodiments of the present inventive concept, the sixth depth D6 and the seventh depth D7 may have substantially the same value as each other. For example, each of the sixth depth D6 and the seventh depth D7 may be about 25 nm to about 50 nm.

In a portion of the semiconductor substrate 100 that is adjacent to the upper surface of the semiconductor substrate 100, the source region 142, the second conductivity type well 100W2, the first conductivity type well 100W1, the recess insulating layer 110, and the drain region 144 may be sequentially arranged in the first horizontal direction (e.g., the X direction). For example, in the portion of the semiconductor substrate 100 that is adjacent to the upper surface of the semiconductor substrate 100, the source region 142, the second conductivity type well 100W2, the first conductivity type well 100W1, the recess insulating layer 110, and the drain region 144 may be sequentially arranged in contact with each other in the first horizontal direction (e.g., the X direction).

The source region 142 may be formed to extend from an upper portion of the second conductivity type well 100W2, which is not covered by the dummy gate insulating layer 122 and the gate spacer 136, to lower portions of the gate spacer 136 and the dummy gate insulating layer 122. The drain region 144 may be formed to be spaced apart from the gate spacer 136, the dummy gate insulating layer 122, and the dummy gate electrode layer 124 in the first horizontal direction (e.g., the X direction), with the recess insulating layer 110 therebetween.

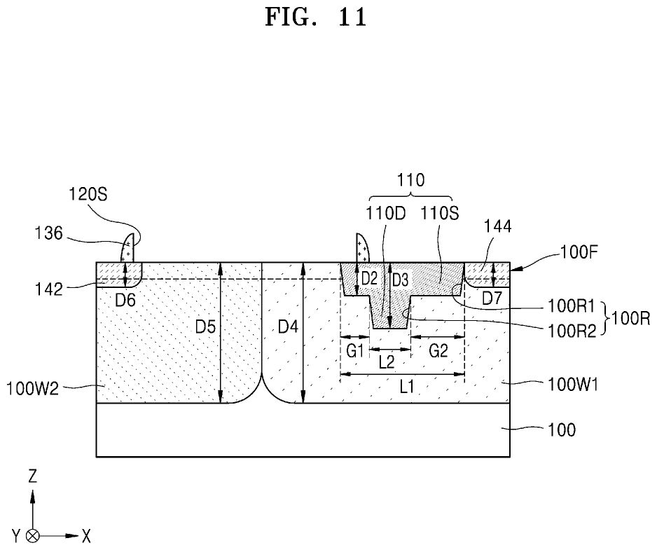

Referring to FIGS. 10 and 11 together, the dummy gate insulating layer 122 and the dummy gate electrode layer 124 may be removed, and the gate spacer 136 may be left above the semiconductor substrate 100. The gate spacer 136 may at least partially surround a removed space 120S where the dummy gate insulating layer 122 and the dummy gate electrode layer 124 have been removed. The removed space 120S may expose a portion of each of the first conductivity type well 100W1, the second conductivity type well 100W2, the source region 142, and the recess insulating layer 110.

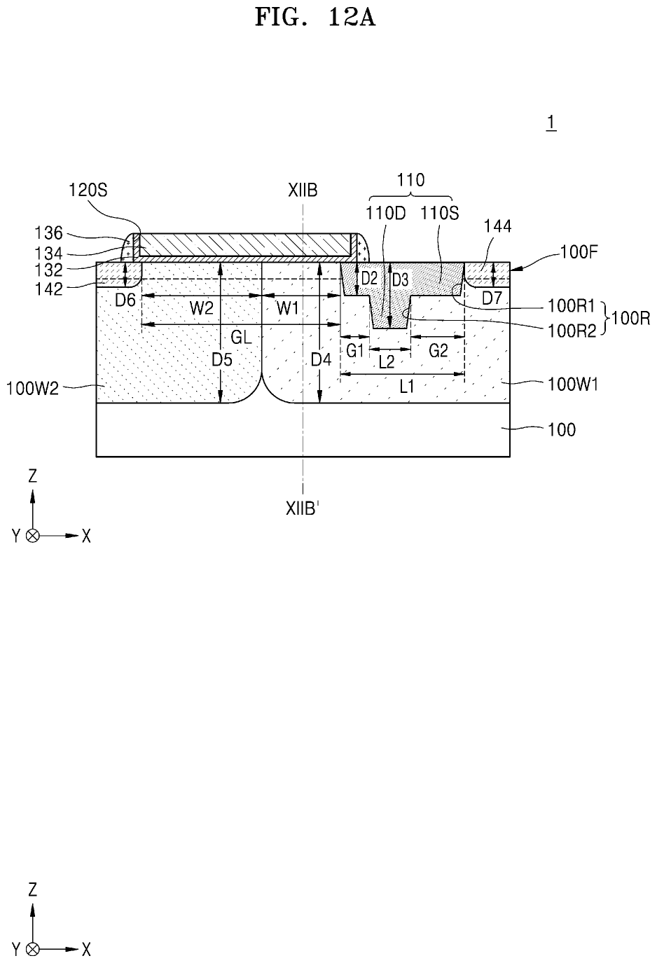

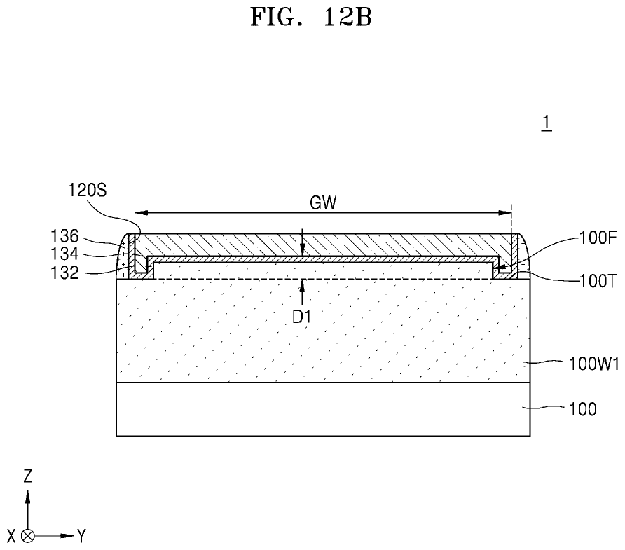

FIGS. 12A and 12B are cross-sectional views of an integrated circuit device 1 according to some embodiments of the present inventive concept. FIGS. 12A and 12B are cross-sectional views taken along portions corresponding to line IIB-IIB′ in FIG. 2A and line IIC-IIC′ in FIG. 2A, respectively.

Referring to FIGS. 12A and 12B together, a gate insulating layer 132 and a gate electrode layer 134 may be formed in the removed space 120S, to form the integrated circuit device 1. The integrated circuit device 1 may include an LDMOS transistor including the fin-type active region 100F, the gate insulating layer 132, the gate electrode layer 134, the source region 142, and the drain region 144.

The gate insulating layer 132 may include, for example, a silicon oxide layer, a high dielectric layer, or a combination thereof. In some embodiments of the present inventive concept, the gate insulating layer 132 may have a stacked structure including an interfacial layer and a high dielectric layer. In some embodiments of the present inventive concept, the interface layer may include a low dielectric material layer having a dielectric constant of about 9 or less, for example, silicon oxide, silicon oxynitride, or a combination thereof. In some embodiments of the present inventive concept, the interface layer may be omitted. The high dielectric layer may include a material having a dielectric constant higher than that of silicon oxide. For example, the high dielectric layer may have a dielectric constant of about 10 to about 25.

The high dielectric layer may include, for example, hafnium oxide, hafnium oxynitride, hafnium silicon oxide, lanthanum oxide, lanthanum aluminum oxide, zirconium oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof, but the material constituting the high dielectric layer is not necessarily limited thereto. The high dielectric layer may be formed by performing, for example, an atomic layer deposition (ALD) process, a chemical vapor deposition (CVD) process, or a physical vapor deposition (PVD) process. The high dielectric layer may have a thickness of about 10 Å to about 40 Å, but the present inventive concept is not necessarily limited thereto.

In some embodiments of the present inventive concept, the gate insulating layer 132 may include a ferroelectric material layer having ferroelectric characteristics, or a paraelectric material layer having paraelectric characteristics. For example, the gate insulating layer 132 may include one ferroelectric material layer. For example, the gate insulating layer 132 may include a plurality of ferroelectric material layers spaced apart from each other. For example, the gate insulating layer 132 may have a stacked layer structure in which a plurality of ferroelectric material layers and a plurality of paraelectric material layers are alternately stacked on each other.

The gate electrode layer 134 may include, for example, conductive polysilicon, a metal, conductive metal nitride, or a combination thereof. The metal and conductive metal nitride may include at least one metal of, for example, Ti, Ta, W, Ru, Nb, Mo, and Hf, but the present inventive concept is not necessarily limited thereto. Metal nitride may include, for example, TiN, TaN, or a combination thereof, but the present inventive concept is not necessarily limited thereto.

In some embodiments of the present inventive concept, the gate electrode layer 134 may include a work function control metal-included layer and a gap-fill metal-included layer filling an upper space of the working function control metal-included layer. The work-function control metal-included layer may include at least one metal of, for example, Ti, W, Ru, Nb, Mo, Hf, Ni, Co, Pt, Yb, Tb, Dy, Er, and Pd. For example, the gap-fill metal-included layer may include W.

In some embodiments of the present inventive concept, the gate electrode layer 134 may have a stacked structure of TiAlC/TiN/W, a stacked structure of TiN/TaN/TiAlC/TiN/W, or a stacked structure of TiN/TaN/TiN/TiAlC/TiN/W, but the present inventive concept is not necessarily limited thereto. In some embodiments of the present inventive concept, the gate electrode layer 134 may have a structure in which a metal nitride layer, a metal layer, a conductive capping layer, and a gap-fill metal layer are sequentially stacked on each other. The metal nitride layer and the metal layer may include at least one metal of, for example, Ti, Ta, W, Ru, Nb, Mo, and Hf. The gap-fill metal layer may include, for example, a W layer or an Al layer.

The gate insulating layer 132 may be formed to conformally cover a surface that is exposed in the removed space 120S. For example, the gate insulating layer 132 may be formed to conformally cover side surfaces of the gate spacer 136 that are exposed in the removal space 120S, the top surface and the side surfaces of the fin-type active region 100F, and the bottom surface of the substrate trench 100T. The upper surface of the fin-type active region 100F that is covered by the gate insulating layer 132 may include a portion of the upper surface of the first conductivity type well 100W1 and a portion of the upper surface of the second conductivity type well 100W2.

The gate electrode layer 134 may cover the gate insulating layer 132 and fill the removed space 120S. For example, the gate electrode layer 134, which is disposed on the gate insulating layer 132, may be spaced apart from the gate spacer 136, the fin-type active region 100F, and the semiconductor substrate 100 exposed to a bottom surface of the substrate trench 100T. The gate electrode layer 134 may be spaced apart from the first conductivity type well 100W1 and the second conductivity type well 100W2. For example, the gate electrode layer 134 may be spaced apart from the first conductivity type well 100W1 and the second conductivity type well 100W2 by the gate insulating layer 132.

The gate electrode layer 134 may have a gate length GL in the first horizontal direction (e.g., the X direction), and a gate width GW in the second horizontal direction (e.g., the Y direction). In some embodiments of the present inventive concept, the gate width GW may be greater than the gate length GL. The gate length GL of the gate electrode layer 134 may be a length of a portion of the gate electrode layer 134 in the first horizontal direction (e.g., the X direction) and may be overlapping the fin-type active region 100F in the vertical direction (e.g., the Z direction). In some embodiments of the present inventive concept, the gate width GW of the gate electrode layer 134 may have a value obtained by summing the width of the fin-type active region 100F in the second horizontal direction (e.g., the Y direction) and the heights of both side surfaces of the fin-type active region 100F in the vertical direction (e.g., the Z direction). For example, the gate length GL of the gate electrode layer 134 may be about 800 nm to about 1.5 μm, and the gate width GW may be about 1 μm to about 5.1 μm.

In the vertical direction (e.g., the Z direction), the gate electrode layer 134 may overlap each of the first conductivity type well 100W1 and the second conductivity type well 100W2. A portion of the integrated circuit device 1 where the gate electrode layer 134 overlaps the first conductivity type well 100W1 in the vertical direction (e.g., the Z direction) may have a first overlapping distance W1 in the first horizontal direction (e.g., the X direction), and a portion of the integrated circuit device 1 where the gate electrode layer 134 overlaps the second conductivity type well 100W2 in the vertical direction (e.g., the Z direction) may have a second overlapping distance W2. For example, where the gate electrode layer 134 overlaps the first conductivity type well 100W1 in the vertical direction (e.g., the Z direction), the first overlapping distance W1 may extend between a side surface of the first conductivity type well 100W1 and a side surface of the upper insulating unit 100S. For example, where the gate electrode layer 134 overlaps the second conductivity type well 100W2 in the vertical direction (e.g., the Z direction), the second overlapping distance W2 may extend between a side surface of the source region 142 and a side surface of the second conductivity type well 100W2. The second overlapping distance W2 may be greater than the first overlapping distance W1. In some embodiments of the present inventive concept, the second overlapping distance W2 may be at least twice the first overlapping distance W1. For example, the first overlapping distance W1 may be about 250 nm to about 500 nm, and the second overlapping distance W2 may be about 550 nm to about 1 μm. The sum of the first overlapping distance W1 and the second overlapping distance W2 may be equal to the gate length GL.

The fin-type active region 100F may have a height equal to the first depth D1 in the vertical direction (e.g., the Z direction). The fin-type active region 100F may have a height of several tens of A in the vertical direction (e.g., the Z direction). For example, the fin-type active region 100F may have a height of about 30 Å to about 50 Å in the vertical direction (e.g., the Z direction).

The substrate recess 100R may include the upper substrate recess 100R1, which extends from the upper surface of the first conductivity type well 100W1 to the inside of the first conductivity type well 100W1, and the lower substrate recess 100R2, which is interconnected to the upper substrate recess 100R1 and extends from the bottom surface of the upper substrate recess 100R1 to the inside of the first conductivity type well 100W1. The recess insulating layer 110 may be arranged between the stacked structure of the gate insulating layer 132 and the gate electrode layer 134, and the drain region 144. The recess insulating layer 110 may include an upper insulating unit 110S, which fills the upper substrate recess 100R1, and a lower insulating unit 110D, which fills the lower substrate recess 100R2.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length. For example, the upper insulating unit 110S may have an equilateral trapezoidal cross-section with a bottom side smaller than a top side in the X-Z plane, and the first length L1 of the upper insulating unit 110S may be the length of the top side having the largest length. The first length L1 may be several hundreds of nm. For example, the first length L1 may be about 400 nm to about 800 nm.

The upper surface of the upper insulating unit 110S, the upper surface of the fin-type active region 100F, the upper surface of the source region 142, and the upper surface of the drain region 144 may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F. The thickness of the upper insulating unit 110S may be several tens of nm. For example, the thickness of the upper insulating unit 110S may be about 60 nm to about 80 nm.

The lower insulating unit 110D may have the second length L2 that is less than the first length L1 in the first horizontal direction (e.g., the X direction). The lower insulating unit 110D may have a tapered shape extending from a lower surface of the upper insulating unit 110S into the semiconductor substrate 100 with a decreasing length. For example, the lower insulating unit 110D may have an equilateral trapezoidal cross-section with a bottom side smaller than a top side in the X-Z plane, and the second length L2 of the lower insulating unit 110D may be the length of the top side having the largest length. For example, the second length L2 may be about 100 nm to about 300 nm. The thickness of the lower insulating unit 110D may be a difference between the third depth D3 and the second depth D2. For example, the thickness of the lower insulating unit 110D may be about 90 nm to about 240 nm.

In some embodiments of the present inventive concept, the recess insulating layer 110 may have a T-shape on the X-Z plane. The center of the lower insulating unit 110D may be shifted to one side of the upper insulating unit 110S in the first horizontal direction (e.g., the X direction) with respect to the center of the upper insulating unit 110S. For example, the recess insulating layer 110 may have a shape in which both sides thereof are asymmetric with respect to the center of the upper insulating unit 110S in the first horizontal direction (e.g., the X direction). For example, the recess insulating layer 110 may be arranged with the lower insulating part 110D more shifted toward the source region 142 and the gate electrode layer 134 than to the drain region 144, with respect to the center of the upper insulating unit 110S.

According to embodiments of the present inventive concept, one side in the first horizontal direction (e.g., the X direction) may be referred to as a side toward the source region 142, and the other side in the first horizontal direction (e.g., the X direction) may be referred to as a side toward the drain region 144.

One side of the upper insulating unit 110S and one side of the lower insulating unit 110D may be spaced apart from each other by the first gap G1 in the first horizontal direction (e.g., the X direction), and the other side of the upper insulating unit 110S and the other side of the lower insulating unit 110D may be spaced apart from each other by the second gap G2 that is different from the first gap G1. In some embodiments of the present inventive concept, the first gap G1 may be less than the second gap G2. For example, the first gap G1 may be about 100 nm to about 200 nm, and the second gap G2 may be about 200 nm to about 300 nm. In some embodiments of the present inventive concept, the first gap G1 may be less than the second length L2.

The first conductivity type well 100W1 may be formed to have the fourth depth D4, which is greater than the third depth D3, from the upper surface of the fin-type active region 100F and/or the upper surface of the recess insulating layer 110. The first conductivity type well 100W1 may be formed to have the lower surface lower than the lower surface of the recess insulating layer 110, and to surround the side surfaces and the lower surface of the recess insulating layer 110. The second conductivity type well 100W2 may be formed to have the fifth depth D5, which is greater than the third depth D3, from the upper surface of the fin-type active region 100F and/or the upper surface of the recess insulating layer 110. In some embodiments of the present inventive concept, the fifth depth D5 may be substantially the same as the fourth depth D4, but the present inventive concept is not necessarily limited thereto. The upper surface of the first conductivity type well 100W1 and the upper surface of the second conductivity type well 100W2 may be at substantially the same vertical level as each other to be substantially coplanar with each other.

The source region 142 may have the lower surface at the sixth depth D6, which is greater than the first depth D1, from the upper surface of the fin-type active region 100F, and the drain region 144 may have the lower surface at the seventh depth D7, which is greater than the first depth D1, from the upper surface of the fin-type active region 100F. In some embodiments of the present inventive concept, the sixth depth D6 and the seventh depth D7 may have substantially the same value as each other. In some embodiments of the present inventive concept, each of the sixth depth D6 and the seventh depth D7 may be less than the second depth D2. For example, each of the sixth depth D6 and the seventh depth D7 may be about 25 nm to about 50 nm.

In a portion of the semiconductor substrate 100, that is adjacent to the upper surface of the semiconductor substrate 100, the source region 142, the second conductivity type well 100W2, the first conductivity type well 100W1, the recess insulating layer 110, and the drain region 144 may be sequentially arranged in the first horizontal direction (e.g., the X direction).

In the integrated circuit device 1 according to embodiments of the present inventive concept, a current path between the source region 142 and the drain region 144 may be formed along the bottom surface of the recess insulating layer 110. Accordingly, the current path of the integrated circuit device 1 may be formed along a portion of the fin-type active region 100F, which is between the source region 142 and the recess insulating layer 110, along a portion of the first conductivity type well 100W1, which is on the side and bottom surfaces of the upper insulating unit 110S and the lower insulating unit 110D, and up to the drain region 144.

The current path of the integrated circuit device 1 may be formed not only along a portion of the first conductivity type well 100W1, which is under the upper insulating unit 110S that is relatively close to the fin-type active region 100F, but also along a portion of the first conductivity type well 100W1 that is disposed under the fin-type active region 100F. Accordingly, the integrated circuit device 1 may minimize hot carrier injection (HCl), and thus, may have electrical characteristics with increased reliability.

In addition, the recess insulating layer 110 may have a shape in which both sides thereof are asymmetric with respect to the center of the upper insulating unit 110S in the first horizontal direction (e.g., the X direction). For example, the center of the lower insulating unit 110D may be more shifted to one side of the upper insulating unit 110S than to another side in the first horizontal direction (e.g., the X direction) with respect to the center of the upper insulating unit 110S. Thus, by determining the position of the lower insulating unit 110D by adjusting the first gap G1 and the second gap G2, a highly scaled high-integration integrated circuit device 1 may be provided.

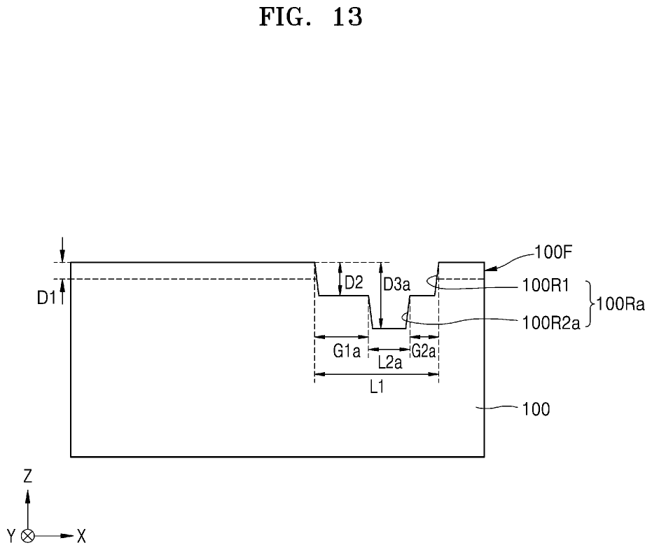

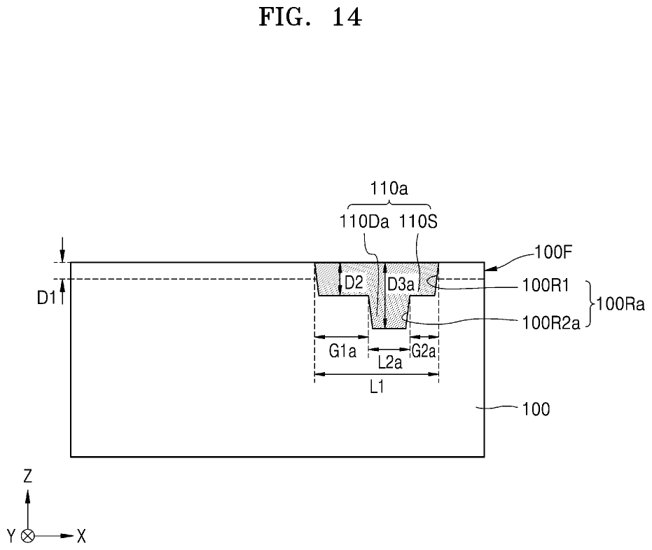

FIGS. 13 and 14 are cross-sectional views describing a method of manufacturing a semiconductor device, according to an embodiment of the present inventive concept. FIGS. 13A and 14 are cross-sectional views illustrating operations after the operation illustrated in FIG. 3.

Referring to FIG. 13, by etching a portion of the semiconductor substrate 100, a lower substrate recess 100R2a may be formed. The lower substrate recess 100R2a may be interconnected to the upper substrate recess 100R1. For example, the lower substrate recess 100R2a may be formed by removing a portion of the semiconductor substrate 100 and penetrating the bottom surface of the upper substrate recess 100R1. The lower substrate recess 100R2a may have a third depth D3a, which is greater than the second depth D2, from the upper surface of the fin-type active region 100F. The third depth D3a may be several hundreds of nm. For example, the third depth D3a may be about 150 nm to about 300 nm. The depth of the lower substrate recess 100R2a from the bottom of the upper substrate recess 100R1 may be a difference between the third depth D3a and the second depth D2. For example, the depth of the lower substrate recess 100R2a from the bottom of the upper substrate recess 100R1 may be about 90 nm to about 240 nm. The depth of the lower substrate recess 100R2a from the bottom of the upper substrate recess 100R1 may be greater than the second depth D2.

The upper substrate recess 100R1 and the lower substrate recess 100R2a, which are interconnected to each other, may be referred to as the substrate recess 100Ra. In some embodiments of the present inventive concept, the substrate recess 100Ra may have a T-shape on the X-Z plane.

The lower substrate recess 100R2a may have a second length L2a shorter than the first length L1 in the first horizontal direction (e.g., the X direction). In some embodiments of the present inventive concept, the lower substrate recess 100R2a may have a tapered shape which extends into the semiconductor substrate 100 with a decreasing length. For example, the lower substrate recess 100R2a may have an equilateral trapezoidal cross-section with a bottom side less than a top side in the X-Z plane, and the second length L2a of the lower substrate recess 100R2a may be the length of the top side having the largest length. For example, the second length L2a may be about 100 nm to about 300 nm.

The center of the lower substrate recess 100R2a may be shifted to the other side of the upper substrate recess 100R1 in the first horizontal direction (e.g., the X direction) with respect to the center of the upper substrate recess 100R1. For example, the substrate recess 100Ra may have a shape in which both sides thereof are asymmetric with respect to the center of the upper substrate recess 100R1 in the first horizontal direction (X direction).

One side of the upper substrate recess 100R1 and one side of the lower substrate recess 100R2a may be spaced apart from each other by a first gap G1a in the first horizontal direction (e.g., the X direction), and the other side of the upper substrate recess 100R1 and the other side of the lower substrate recess 100R2a may be spaced apart from each other by a second gap G2a that is different from the first gap G1a. In some embodiments of the present inventive concept, the first gap G1a may be greater than the second gap G2a. For example, the first gap G1a may be about 200 nm to about 300 nm, and the second gap G2a may be about 100 nm to about 200 nm. In some embodiments of the present inventive concept, the first gap G1a may be greater than the second length L2a.

Referring to FIG. 14, a recess insulating layer 110a filling the substrate recess 100Ra may be formed. The recess insulating layer 100a may include, for example, an oxide. The recess insulating layer 110a may include an upper insulating unit 110S, which fills the upper substrate recess 100R1, and a lower insulating unit 110Da, which fills the lower substrate recess 100R2a. Because the lower insulating unit 110Da is a portion of the recess insulating layer 110a filling the lower substrate recess 100R2a that is interconnected to the upper substrate recess 100R1, the lower insulating unit 110Da may be arranged below the upper insulating unit 110S, and may overlap the upper insulating unit 110S in the vertical direction (e.g., the Z direction). The upper insulating unit 110S and the lower insulating unit 110Da may be formed together, and may include the same material as each other. In addition, the upper insulating unit 110S and the lower insulating unit 110Da may be one body. For example, the upper insulating unit 110S and the lower insulating unit 110Da may be referred to as a shallow insulating unit and a deep insulating unit.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length. The top surfaces of the upper insulating unit 110S and the fin-type active region 100F may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F.

The lower insulating unit 110Da may have the second length L2a less than the first length L1 in the first horizontal direction (e.g., the X direction). The lower insulating unit 110Da may have a tapered shape extending from a lower surface of the upper insulating unit 110S into the semiconductor substrate 100 with a decreasing length. For example, the lower insulating unit 110Da may have an equilateral trapezoidal cross-section with a bottom side less than a top side in the X-Z plane, and the second length L2a of the lower insulating unit 110Da may be the length of the top side having the largest length. For example, the second length L2a may be about 100 nm to about 300 nm.

The thickness of the lower insulating unit 110Da may be a difference between the third depth D3a and the second depth D2. For example, the thickness of the lower insulating unit 110Da may be about 90 nm to about 240 nm.

The center of the lower insulating unit 110Da may be shifted to the other side of the upper insulating unit 110S in the first horizontal direction (e.g., the X direction) with respect to the center of the upper insulating unit 110S. For example, the recess insulating layer 110a may have a shape in which both sides thereof are asymmetric with respect to the center of the upper insulating unit 110S in the first horizontal direction (e.g., the X direction).

One side of the upper insulating unit 110S and one side of the lower insulating unit 110Da may be spaced apart from each other by the first gap G1a in the first horizontal direction (e.g., the X direction), and the other side of the upper insulating unit 110S and the other side of the lower insulating unit 110Da may be spaced apart from each other by the second gap G2a that is different from the first gap G1a. In some embodiments of the present inventive concept, the first gap G1a may be greater than the second gap G2a. For example, the first gap G1a may be about 200 nm to about 300 nm, and the second gap G2a may be about 100 nm to about 200 nm. In some embodiments of the present inventive concept, the first gap G1a may be greater than the second length L2a.

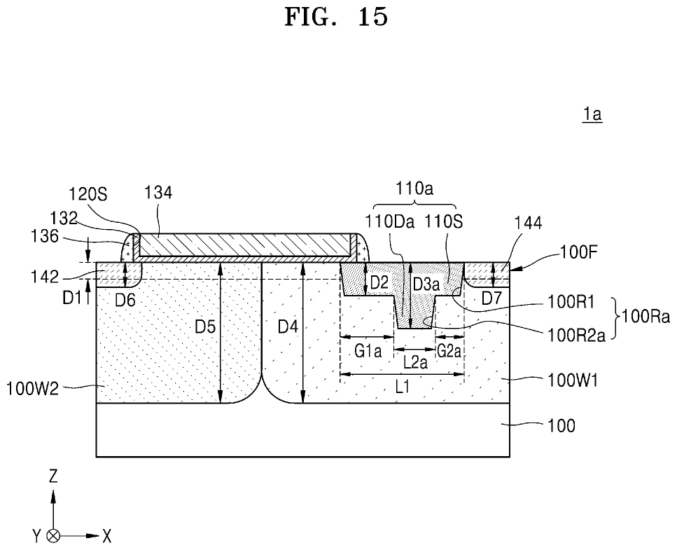

FIG. 15 is a cross-sectional view of an integrated circuit device 1a according to an embodiment of the present inventive concept. FIG. 15 is a cross-sectional view taken along a portion corresponding to line IIB-IIB′ in FIG. 2A.

Referring to FIG. 15, by performing the method described above with respect to FIGS. 6 through 12B on the resultant product of FIG. 14 to form the first conductivity type well 100W1, the second conductivity type well 100W2, the gate spacer 136, the gate insulating layer 132, and the gate electrode layer 134, the integrated circuit device 1a may be formed. The integrated circuit device 1a may include an LDMOS transistor including the fin-type active region 100F, the gate insulating layer 132, the gate electrode layer 134, the source region 142, and the drain region 144.

The substrate recess 100Ra may include the upper substrate recess 100R1, which extends from the upper surface of the first conductivity type well 100W1 to the inside of the first conductivity type well 100W1, and the lower substrate recess 100R2a, which is interconnected to the upper substrate recess 100R1 and extends from the bottom surface of the upper substrate recess 100R1 to the inside of the first conductivity type well 100W1. The recess insulating layer 110a may be arranged between a stacked structure, which includes the gate insulating layer 132 and the gate electrode layer 134, and the drain region 144. The recess insulating layer 110a may include an upper insulating unit 110S, which fills the upper substrate recess 100R1, and a lower insulating unit 110Da, which fills the lower substrate recess 100R2a.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length.

The upper surface of the upper insulating unit 110S, the upper surface of the fin-type active region 100F, the upper surface of the source region 142, and the upper surface of the drain region 144 may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F.

The lower insulating unit 110Da may have the second length L2a that is less than the first length L1 in the first horizontal direction (e.g., the X direction). The lower insulating unit 110Da may have a tapered shape extending from a lower surface of the upper insulating unit 110S into the semiconductor substrate 100 with a decreasing length. For example, the lower insulating unit 110Da may have an equilateral trapezoidal cross-section with a bottom side smaller than a top side in the X-Z plane, and the second length L2a of the lower insulating unit 110Da may be the length of the top side having the largest length.

In some embodiments of the present inventive concept, the recess insulating layer 110a may have a T-shape on the X-Z plane. The center of the lower insulating unit 110Da may be shifted to the other side of the upper insulating unit 110S in the first horizontal direction (e.g., the X direction) with respect to the center of the upper insulating unit 110S. For example, the recess insulating layer 110a may have a shape in which both sides thereof are asymmetric with respect to the center of the upper insulating unit 110S in the first horizontal direction (e.g., the X direction). For example, the recess insulating layer 110a may be arranged with the lower insulating part 110Da more shifted toward the drain region 144 than to the source region 142 and the gate electrode layer 134, with respect to the center of the upper insulating unit 110S.

One side of the upper insulating unit 110S and one side of the lower insulating unit 110Da may be spaced apart from each other by the first gap G1a in the first horizontal direction (e.g., the X direction), and the other side of the upper insulating unit 110S and the other side of the lower insulating unit 110Da may be spaced apart from each other by the second gap G2a that is different from the first gap G1a. In some embodiments of the present inventive concept, the first gap G1a may be greater than the second gap G2a. In some embodiments of the present inventive concept, the first gap G1a may be greater than the second length L2a.

The first conductivity type well 100W1 may be formed to have the fourth depth D4, which is greater than the third depth D3a, from the upper surface of the fin-type active region 100F and/or the upper surface of the recess insulating layer 110a. The first conductivity type well 100W1 may be formed to have a lower surface lower than the lower surface of the recess insulating layer 110a, and to surround the side surfaces and the lower surface of the recess insulating layer 110a.

The second conductivity type well 100W2 may be formed to have the fifth depth D5, which is greater than the third depth D3a, from the upper surface of the fin-type active region 100F and/or the upper surface of the recess insulating layer 110a. In some embodiments of the present inventive concept, the fifth depth D5 may be substantially the same as the fourth depth D4, but the present inventive concept is not necessarily limited thereto.

The source region 142 may have a lower surface at the sixth depth D6, which is greater than the first depth D1, from the upper surface of the fin-type active region 100F, and the drain region 144 may have a lower surface at the seventh depth D7, which is greater than the first depth D1, from the upper surface of the fin-type active region 100F. In some embodiments of the present inventive concept, the sixth depth D6 and the seventh depth D7 may have substantially the same value as each other. In some embodiments of the present inventive concept, each of the sixth depth D6 and the seventh depth D7 may be less than the second depth D2.

In a portion of the semiconductor substrate 100, that is adjacent to the upper surface of the semiconductor substrate 100, the source region 142, the second conductivity type well 100W2, the first conductivity type well 100W1, the recess insulating layer 110a, and the drain region 144 may be sequentially arranged in the first horizontal direction (e.g., the X direction).

In the integrated circuit device 1a according to embodiments of the present inventive concept, a current path between the source region 142 and the drain region 144 may be formed along the bottom surface of the recess insulating layer 110a. Accordingly, the current path of the integrated circuit device 1a may be formed along a portion of the fin-type active region 100F, which is between the source region 142 and the recess insulating layer 110a, along a portion of the first conductivity type well 100W1, which is on the side and bottom surfaces of the upper insulating unit 110S and the lower insulating unit 110Da, and up to the drain region 144. Accordingly, the integrated circuit device 1a may minimize HCl, and thus may have electrical characteristics with increased reliability.

In addition, the recess insulating layer 110a may have a shape in which both sides thereof are asymmetric with respect to the center of the upper insulating unit 110S in the first horizontal direction (e.g., the X direction). For example, the center of the lower insulating unit 110Da may be shifted to the other side of the upper insulating unit 110S in the first horizontal direction (e.g., the X direction) with respect to the center of the upper insulating unit 110S. Thus, by determining the position of the lower insulating unit 100Da by adjusting the first gap G1a and the second gap G2a, a highly scaled high-integration integrated circuit device 1a may be provided.

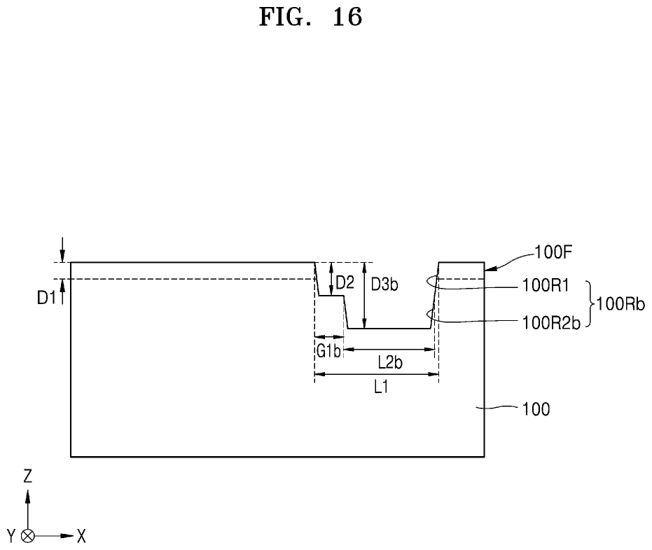

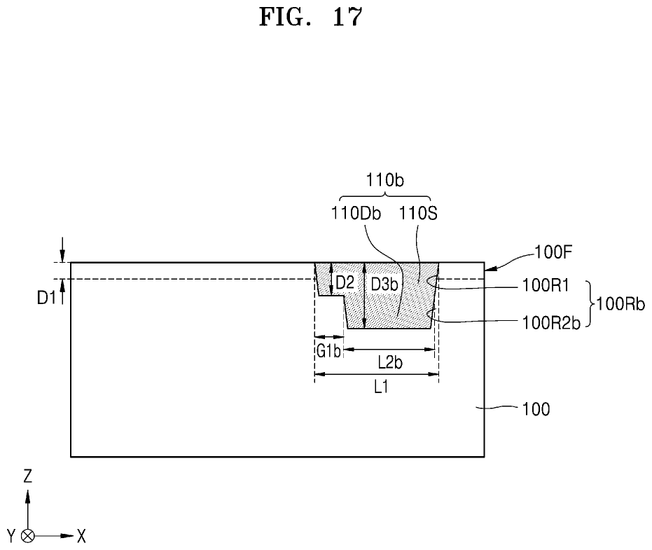

FIGS. 16 and 17 are cross-sectional views describing a method of manufacturing a semiconductor device, according to an embodiment of the present inventive concept. FIGS. 16 and 17 are cross-sectional views illustrating operations after the operation illustrated in FIG. 3.

Referring to FIG. 16, by etching a portion of the semiconductor substrate 100, a lower substrate recess 100R2b may be formed. The lower substrate recess 100R2b may be interconnected to the upper substrate recess 100R1. For example, the lower substrate recess 100R2b may be formed by removing a portion of the semiconductor substrate 100 and penetrating through the bottom surface of the upper substrate recess 100R1. The lower substrate recess 100R2b may have a third depth D3b, which is greater than the second depth D2, from the upper surface of the fin-type active region 100F. The third depth D3b may be several hundreds of nm. For example, the third depth D3b may be about 150 nm to about 300 nm. The depth of the lower substrate recess 100R2b from the bottom of the upper substrate recess 100R1 may be a difference between the third depth D3b and the second depth D2. For example, the depth of the lower substrate recess 100R2b from the bottom of the upper substrate recess 100R1 may be about 90 nm to about 240 nm. The depth of the lower substrate recess 100R2b from the bottom of the upper substrate recess 100R1 may be greater than the second depth D2.

The upper substrate recess 100R1 and the lower substrate recess 100R2b, which are interconnected to each other, may be referred to as a substrate recess 100Rb. In some embodiments of the present inventive concept, the substrate recess 100Rb may have an upside down L-shape on the X-Z plane. For example, a side surface of the upper substrate recess 100R1 and a side surface of the lower substrate recess 100R2b may be substantially coplanar.

The lower substrate recess 100R2b may have a second length L2b shorter than the first length L1 in the first horizontal direction (e.g., the X direction). In some embodiments of the present inventive concept, the lower substrate recess 100R2b may have a tapered shape which extends into the semiconductor substrate 100 with a decreasing length. For example, the lower substrate recess 100R2b may have an equilateral trapezoidal cross-section with a bottom side smaller than a top side in the X-Z plane, and the second length L2b of the lower substrate recess 100R2b may be the length of the top side having the largest length. For example, the second length L2b may be about 300 nm to about 600 nm.

The center of the lower substrate recess 100R2b may be shifted to the other side of the upper substrate recess 100R1 in the first horizontal direction (e.g., the X direction) with respect to the center of the upper substrate recess 100R1. For example, the lower substrate recess 100R2b may have a shape in which both sides thereof are asymmetric with respect to the center of the upper substrate recess 100R1 in the first horizontal direction (e.g., the X direction). The other side of the lower substrate recess 100R2b may be in contact with the other side of the upper substrate recess 100R1 in the first horizontal direction (e.g., the X direction).

One side of the upper substrate recess 100R1 and one side of the lower substrate recess 100R2b may be spaced apart from each other by a first gap G1b in the first horizontal direction (e.g., the X direction), and the other side of the upper substrate recess 100R1 and the other side of the lower substrate recess 100R2b might not be spaced apart from but may be in contact with each other. In some embodiments of the present inventive concept, the first gap G1b may be less than the second length L2b. For example, the first gap G1b may be about 100 nm to about 200 nm.

Referring to FIG. 17, a recess insulating layer 110b filling the substrate recess 100Rb may be formed. The recess insulating layer 110b may include, for example, an oxide. The recess insulating layer 110b may include an upper insulating unit 110S, which fills the upper substrate recess 100R1, and a lower insulating unit 110Db, which fills the lower substrate recess 100R2b. Because the lower insulating unit 110Db is a portion of the recess insulating layer 110b, which fills the lower substrate recess 100R2b that is interconnected to the upper substrate recess 100R1, the lower insulating unit 110Db may be arranged below the upper insulating unit 110S, and may overlap the upper insulating unit 110S in the vertical direction (e.g., the Z direction). The upper insulating unit 110S and the lower insulating unit 110Db may be formed together, and may include the same material as each other. In addition, the upper insulating unit 110S and the lower insulating unit 110Db make one body. For example, the upper insulating unit 110S and the lower insulating unit 110Db may be referred to as a shallow insulating unit and a deep insulating unit.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length. The top surfaces of the upper insulating unit 110S and the fin-type active region 100F may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F.

The lower insulating unit 110Db may have the second length L2b less than the first length L1 in the first horizontal direction (e.g., the X direction). The lower insulating unit 110Db may have a tapered shape extending from a lower surface of the upper insulating unit 110S into the semiconductor substrate 100 with a decreasing length. For example, the lower insulating unit 110Db may have an equilateral trapezoidal cross-section with a bottom side smaller than a top side in the X-Z plane, and the second length L2b of the lower insulating unit 110Db may be the length of the top side having the largest length. For example, the second length L2b may be about 300 nm to about 600 nm.

The thickness of the lower insulating unit 110Db may be a difference between the third depth D3b and the second depth D2. For example, the thickness of the lower insulating unit 110Db may be about 90 nm to about 240 nm.

The center of the lower insulating unit 110Db may be shifted to one side of the upper insulating unit 110S in the first horizontal direction (e.g., the X direction) with respect to the center of the upper insulating unit 110S. For example, the recess insulating layer 110b may have a shape in which both sides thereof are asymmetric with respect to the center of the upper insulating unit 110S in the first horizontal direction (e.g., the X direction).

One side of the upper insulating unit 110S and one side of the lower insulating unit 110Db may be spaced apart from each other by the first gap G1b in the first horizontal direction (e.g., the X direction), and the other side of the upper insulating unit 110S and the other side of the lower insulating unit 110Db might not be spaced apart from but may be in contact with each other. In some embodiments of the present inventive concept, the first gap G1b may be less than the second length L2b. For example, the first gap G1b may be about 100 nm to about 200 nm.

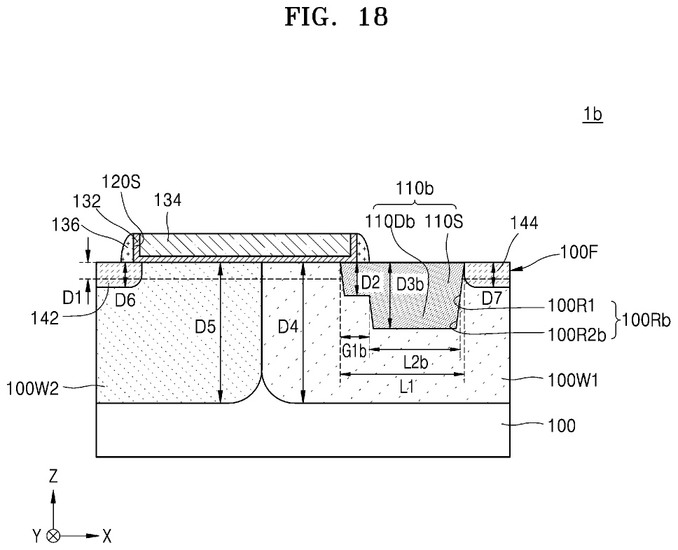

FIG. 18 is a cross-sectional view of the integrated circuit device 1b according to an embodiment of the present inventive concept. FIG. 18 is a cross-sectional view taken along a portion corresponding to line IIB-IIB′ in FIG. 2A.

Referring to FIG. 18, by performing the method described above with respect to FIGS. 6 through 12B on the resultant product of FIG. 17 to form the first conductivity type well 100W1, the second conductivity type well 100W2, the gate spacer 136, the gate insulating layer 132, and the gate electrode layer 134, the integrated circuit device 1b may be formed. The integrated circuit device 1b may include an LDMOS transistor including the fin-type active region 100F, the gate insulating layer 132, the gate electrode layer 134, the source region 142, and the drain region 144.

The substrate recess 100Rb may include the upper substrate recess 100R1, which extends from the upper surface of the first conductivity type well 100W1 to the inside of the first conductivity type well 100W1, and the lower substrate recess 100R2b, which is interconnected to the upper substrate recess 100R1 and extends from the bottom surface of the upper substrate recess 100R1 to the inside of the first conductivity type well 100W1. The recess insulating layer 110b may be arranged between a stacked structure, which includes the gate insulating layer 132 and the gate electrode layer 134, and the drain region 144. The recess insulating layer 110b may include an upper insulating unit 110S, which fills the upper substrate recess 100R1, and a lower insulating unit 110Db, which fills the lower substrate recess 100R2b.

The upper insulating unit 110S may have the first length L1 in the first horizontal direction (e.g., the X direction). In some embodiments of the present inventive concept, the upper insulating unit 110S may have a tapered shape which extends into the semiconductor substrate 100 with a decreasing length.

The upper surface of the upper insulating unit 110S, the upper surface of the fin-type active region 100F, the upper surface of the source region 142, and the upper surface of the drain region 144 may be at substantially the same vertical level as each other to be substantially coplanar with each other. The thickness of the upper insulating unit 110S may have a value substantially the same as the second depth D2, which is the depth of the upper substrate recess 100R1 from the upper surface of the fin-type active region 100F.

The lower insulating unit 110Db may have the second length L2b that is less than the first length L1 in the first horizontal direction (e.g., the X direction). The lower insulating unit 110Db may have a tapered shape extending from a lower surface of the upper insulating unit 110S into the semiconductor substrate 100 with a decreasing length. For example, the lower insulating unit 110Db may have an equilateral trapezoidal cross-section with a bottom side smaller than a top side in the X-Z plane, and the second length L2b of the lower insulating unit 110Db may be the length of the top side having the largest length.

In some embodiments of the present inventive concept, the recess insulating layer 110b may have an upside down L-shape on the X-Z plane. The center of the lower insulating unit 110Db may be shifted to the other side of the upper insulating unit 110S in the first horizontal direction (e.g., the X direction) with respect to the center of the upper insulating unit 110S. For example, the recess insulating layer 110b may have a shape in which both sides thereof are asymmetric with respect to the center of the upper insulating unit 110S in the first horizontal direction (e.g., the X direction). For example, the recess insulating layer 110b may be arranged with the lower insulating part 110Db more shifted toward the drain region 144 than to the source region 142 and the gate electrode layer 134, with respect to the center of the upper insulating unit 110S.

One side of the upper insulating unit 110S and one side of the lower insulating unit 110Db may be spaced apart from each other by the first gap G1b in the first horizontal direction (e.g., the X direction), and the other side of the upper insulating unit 110S and the other side of the lower insulating unit 110Db might not be spaced apart from but may be in contact with each other. For example, the other side of the upper insulating unit 110S and the other side of the lower insulating unit 110Db may be substantially coplanar. In some embodiments of the present inventive concept, the first gap G1b may be less than the second length L2b.

The first conductivity type well 100W1 may be formed to have the fourth depth D4, which is greater than the third depth D3b, from the upper surface of the fin-type active region 100F and/or the upper surface of the recess insulating layer 110b. The first conductivity type well 100W1 may be formed to have the lower surface lower than the lower surface of the recess insulating layer 110b, and to surround the side surfaces and the lower surface of the recess insulating layer 110b.

The second conductivity type well 100W2 may be formed to have the fifth depth D5, which is greater than the third depth D3b, from the upper surface of the fin-type active region 100F and/or the upper surface of the recess insulating layer 110b. In some embodiments of the present inventive concept, the fifth depth D5 may be substantially the same as the fourth depth D4, but the present inventive concept is not necessarily limited thereto.

The source region 142 may have a lower surface at the sixth depth D6, which is greater than the first depth D1, from the upper surface of the fin-type active region 100F, and the drain region 144 may have a lower surface at the seventh depth D7, which is greater than the first depth D1, from the upper surface of the fin-type active region 100F. In some embodiments of the present inventive concept, the sixth depth D6 and the seventh depth D7 may have substantially the same value as each other. In some embodiments of the present inventive concept, each of the sixth depth D6 and the seventh depth D7 may be less than the second depth D2.

In a portion of the semiconductor substrate 100, which is adjacent to the upper surface of the semiconductor substrate 100, the source region 142, the second conductivity type well 100W2, the first conductivity type well 100W1, the recess insulating layer 10b, and the drain region 144 may be sequentially arranged in in the first horizontal direction (e.g., the X direction).

In the integrated circuit device 1b according to embodiments of the present inventive concept, a current path between the source region 142 and the drain region 144 may be formed along the bottom surface of the recess insulating layer 110b. Accordingly, the current path of the integrated circuit device 1b may be formed along a portion of the fin-type active region 100F, which is between the source region 142 and the recess insulating layer 110b, along a portion of the first conductivity type well 100W1, which is on the side and bottom surfaces of the upper insulating unit 110S and the lower insulating unit 110Da, and up to the drain region 144. Accordingly, the integrated circuit device 1b may minimize HCl, and thus may have electrical characteristics with increased reliability.

In addition, by providing a shape, in which both sides of the recess insulating layer 110b are asymmetric with respect to the center of the upper insulating unit 110S in the first horizontal direction (e.g., the X direction), a highly scaled high-integration integrated circuit device 1b may be provided.

While the present inventive concept has been described with reference to example embodiments thereof, it will be understood by those of ordinary skill in the art that various changes in form and details may be made thereto without departing from the spirit and scope of the present inventive concept.

What is claimed is:

1. An integrated circuit device comprising:
a semiconductor substrate;
a first conductivity type well and a second conductivity type well formed in the semiconductor substrate;
a source region formed in the second conductivity type well;
a drain region formed in the first conductivity type well;
a recess insulating layer disposed between the source region and the drain region, and including an upper insulating unit and a lower insulating unit, wherein the upper insulating unit fills an upper substrate recess that extends from an upper surface of the first conductivity type well and into the first conductivity type well, and wherein the lower insulating unit fills a lower substrate recess that extends from a bottom surface of the upper substrate recess and into the first conductivity type well; and
a gate electrode layer disposed between the source region and the recess insulating layer, and arranged on the first conductivity type well and the second conductivity type well, and
wherein the recess insulating layer has a shape in which both sides thereof are asymmetric with respect to a center of the upper insulating unit.

2. The integrated circuit device of claim 1, wherein, in a horizontal direction, the upper insulating unit has a first length, and the lower insulating unit has a second length that is less than the first length.

3. The integrated circuit device of claim 2, wherein the lower insulating unit is more shifted toward the source region with respect to the center of the upper insulating unit in the horizontal direction than to the drain region, and one side of the upper insulating unit, which faces the source region, and one side of the lower insulating unit are spaced apart from each other.

4. The integrated circuit device of claim 2, wherein the lower insulating unit is more shifted toward the drain region with respect to the center of the upper insulating unit in the horizontal direction than to the source region, and one side of the upper insulating unit, which faces the drain region, and one side of the lower insulating unit are spaced apart from each other.

5. The integrated circuit device of claim 2, wherein the lower insulating unit is shifted more toward the drain region with respect to the center of the upper insulating unit in the horizontal direction than to the source region, and one side of the upper insulating unit facing the drain region and one side of the lower insulating unit are substantially coplanar with each other.

6. The integrated circuit device of claim 1, wherein the semiconductor substrate comprises a fin-type active region protruding in a vertical direction, and
the gate electrode layer covers an upper surface and side surfaces of the fin-type active region.

7. The integrated circuit device of claim 6, wherein an upper surface of the upper insulating unit and the upper surface of the fin-type active region are at a substantially identical vertical level, and
a thickness of the upper insulating unit is greater than a protruding height of the fin-type active region.

8. The integrated circuit device of claim 6, wherein a depth, at which a lower surface of each of the source region and the drain region is positioned from the upper surface of the fin-type active region, is greater than a protruding height of the fin-type active region and is less than a thickness of the upper insulating unit.

9. The integrated circuit device of claim 1, wherein a thickness of the lower insulating unit is greater than a thickness of the upper insulating unit.

10. The integrated circuit device of claim 1, wherein a distance in a horizontal direction of a portion where the gate electrode layer overlaps the first conductivity type well in a vertical direction is less than a distance in the horizontal direction of a portion where the gate electrode layer overlaps the second conductivity type well in the vertical direction.

11. An integrated circuit device comprising:
a semiconductor substrate including a fin-type active region protruding in a vertical direction;
a first conductivity type well and a second conductivity type well arranged in a first horizontal direction and in a portion of the semiconductor substrate that includes the fin-type active region;
a source region formed in the second conductivity type well;
a drain region formed in the first conductivity type well;
a recess insulating layer disposed between the source region and the drain region, and including an upper insulating unit and a lower insulating unit, wherein the upper insulating unit extends from an upper surface of the first conductivity type well and into the first conductivity type well, and fills an upper substrate recess having a first length in the first horizontal direction, and wherein the lower insulating unit extends from a bottom surface of the upper substrate recess and into the first conductivity type well, and fills a lower substrate recess having a second length that is less than the first length in the first horizontal direction; and
a gate electrode layer disposed between the source region and the recess insulating layer, and arranged on the first conductivity type well and the second conductivity type well, wherein the gate electrode layer covers an upper surface and side surfaces of the fin-type active region,
wherein the recess insulating layer has a shape in which both sides thereof are asymmetric with respect to a center of the upper insulating unit.

12. The integrated circuit device of claim 11, wherein the recess insulating layer has a T-shape, and
the lower insulating unit is more shifted toward the source region with respect to a center of the upper insulating unit in the first horizontal direction than to the drain region.

13. The integrated circuit device of claim 11, wherein the recess insulating layer has a T-shape, and
the lower insulating unit is more shifted toward the drain region with respect to a center of the upper insulating unit in the first horizontal direction than to the source region.

14. The integrated circuit device of claim 11, wherein the recess insulating layer has an upside down L-shape, and
the lower insulating unit is more shifted toward the drain region with respect to the center of the upper insulating unit in the horizontal direction than to the drain region.

15. The integrated circuit device of claim 11, wherein an upper surface of the upper insulating unit and the upper surface of the fin-type active region are at a substantially identical vertical level, and
wherein a depth of the upper substrate recess is greater than a protruding height of the fin-type active region and is less than a depth of the lower substrate recess.

16. The integrated circuit device of claim 11, wherein a depth, at which a lower surface of each of the source region and the drain region is positioned from the upper surface of the fin-type active region, is greater than a protruding height of the fin-type active region and is less than a depth of the upper substrate recess.

17. The integrated circuit device of claim 11, wherein a gate length of the gate electrode layer in the first horizontal direction is less than a gate width of the gate electrode layer in a second horizontal direction that is substantially perpendicular to the first horizontal direction.

18. An integrated circuit device comprising:
a semiconductor substrate including a fin-type active region protruding in a first direction;
a first conductivity type well and a second conductivity type well arranged in a second direction and in a portion of the semiconductor substrate that includes the fin-type active region;
a source region formed in the second conductivity type well;
a drain region formed in the first conductivity type well;
a recess insulating layer disposed between the source region and the drain region, and including an upper insulating unit and a lower insulating unit, wherein the upper insulating unit extends from an upper surface of the first conductivity type well and into the first conductivity type well, and fills an upper substrate recess having a first length in the second direction, and wherein the lower insulating unit extends from a bottom surface of the upper substrate recess and into the first conductivity type well, and fills a lower substrate recess having a second length that is less than the first length in the second direction;
a gate electrode layer disposed between the source region and the recess insulating layer, and arranged on the first conductivity type well and the second conductivity type well, wherein the gate electrode layer covers an upper surface and side surfaces of the fin-type active region; and
a gate insulating layer arranged between the gate electrode layer and the first conductivity type well, and between the gate electrode layer and the second conductivity type well,
wherein the lower insulating unit is more shifted toward the source region with respect to a center of the upper insulating unit in the second direction than to the drain region, and one side of the upper insulating unit, which faces the source region, and one side of the lower insulating unit are spaced apart from each other, and
wherein the recess insulating layer has a shape in which both sides thereof are asymmetric with respect to the center of the upper insulating unit.

19. The integrated circuit device of claim 18, wherein a thickness of the upper insulating unit is greater than a protruding height of the fin-type active region and is less than a thickness of the lower insulating unit.

20. The integrated circuit device of claim 18, wherein the source region, the second conductivity type well, the first conductivity type well, the recess insulating layer, and the drain region are sequentially arranged adjacent to each other in the second direction in a portion of the semiconductor substrate, which is adjacent to an upper surface of the semiconductor substrate, and
wherein an upper surface of the source region, an upper surface of the second conductivity type well, an upper surface of the first conductivity type well, an upper surface of the recess insulating layer, and an upper surface of the drain region are at a substantially identical vertical level to form a coplanar surface.
